(19) United States
(12) Patent Application Publication
(10) Pub. No.: US 2024/0133955 A1
(43) Pub. Date: Apr. 25, 2024

(54) SYSTEM FOR PERFORMING A MEASUREMENT ON A COMPONENT

(71) Applicant: Cirrus Logic International Semiconductor Ltd., Edinburgh (GB)

(72) Inventors: Aleksey S. KHENKIN, Lago Vista, TX (US); John C. TUCKER, Austin, TX (US); Ravi K. KUMMARAGUNTLA, Austin, TX (US)

(73) Assignee: Cirrus Logic International Semiconductor Ltd., Edinburgh (GB)

(21) Appl. No.: 18/326,238

(22) Filed: May 30, 2023

Related U.S. Application Data
(60) Provisional application No. 63/418,073, filed on Oct. 21, 2022.

(51) Int. Cl. G01R 31/36; G01R 31/385; G01R 31/389; H01M 10/48

(52) U.S. Cl. CPC G01R 31/3648; G01R 31/385; G01R 31/389; H01M 10/48

(57) ABSTRACT

A system for performing a measurement on a component, the system comprising: an integrated circuit (IC) comprising: analog to digital (ADC) converter circuitry; and processing circuitry, wherein the system further comprises: difference circuitry, wherein: the difference circuitry is operable to generate a compensated measurement voltage by subtracting a compensation voltage received from a voltage source external to the integrated circuit from a measurement voltage output by the component in response to a stimulus signal received by the component; the ADC circuitry is configured to convert the compensated measurement voltage into a digital compensated measurement signal; and the measurement circuitry is configured to generate a measurement result based on the digital compensated measurement signal.

### FIELD OF THE INVENTION

The present disclosure relates to a system for performing a measurement on a component, and in particular to a system for performing electrochemical impedance spectrum (EIS) measurements for measuring characteristics of electrochemical cells such as batteries.

### BACKGROUND

Electrochemical impedance spectrum (EIS) measurements can be used for measuring characteristics such as the impedance of an electrochemical cell such as a battery.

FIG. 1 is a schematic representation of an example EIS measurement system. The example EIS measurement system shown generally at 100 in FIG. 1 comprises signal generator circuitry 110 configured to generate an alternating current (AC) stimulus current signal (sometimes also referred to as an EIS driving current) for application to a component 120. The component 120 may be, for example, a battery or other electrochemical cell. It is to be noted that the term component, as used in the present disclosure, encompasses components that consist of a single element (e.g. a battery or other electrochemical cell) as well as components that consist of a plurality of elements assembled to form a component part or subsystem of a larger system.

When the stimulus current signal is applied to the component 120, the component 120 generates an EIS measurement voltage signal in response. Analog to digital converter (ADC) circuitry 130 is coupled to the component 120 to receive this EIS measurement voltage signal and to convert in into a digital signal which is output to EIS processing circuitry 140. The EIS processing circuitry 140 processes the digitised EIS measurement signal to generate one or more EIS measurement outputs, which may be, for example one or more output signals indicative of an impedance of the component 120.

The AC stimulus signal may be a chirp signal or other signal whose frequency varies over a defined frequency range, e.g. 100 millihertz to 10 kilohertz or more, over a defined period of time. Alternatively, the AC stimulus signal may be a wide band signal having components in a range of frequencies, e.g. from 100 millihertz to 10 kilohertz or more. Where the component 120 is a battery or other electrochemical cell, EIS measurement outputs resulting from low frequency components of the AC stimulus current signal (e.g. components of the AC stimulus current signal at frequencies equal to or less than 20 hertz) can contain important information about the state of the battery or cell.

It is desirable to have in-situ EIS capability for systems such as battery monitoring and control devices. For example, it may be desirable to provide an integrated circuit (IC) or chip 150 having a built-in EIS measurement system comprising the signal generator circuitry 110, ADC circuitry 130 and EIS processing circuitry 140. However in an IC or chip having a built-in EIS system, a measurement error can arise for measurements based on the low frequency components of the AC stimulus current signal, due to temperature fluctuations of the IC die of the IC or chip 150 on which the EIS system is implemented.

FIG. 2 illustrates such a measurement error. In the example illustrated in FIG. 2, the EIS measurement outputs comprise a real part of an impedance of a component (which in this case is a battery), shown on the x-axis in FIG. 2, and a negative imaginary part of the impedance of the component, shown on the y-axis. As can be seen in FIG. 2, at frequencies of the AC stimulus current signal below about 20 Hz, a measured response 210 of the component to an AC stimulus current signal generated by signal generator circuitry 110 of an on-chip EIS measurement system differs from an expected response 220 of the component (as determined experimentally by driving the component with an AC stimulus signal generated by an external EIS measurement system). The reason for this measurement error is explained below.

In general an EIS measurement signal output by a component 120 in a system of the kind shown in FIG. 1 comprises a superposition of a small AC voltage signal component Vac (resulting from the AC stimulus current signal applied to the component 120) and a larger DC voltage signal component Vdc (such as a battery voltage) from the component 120. For example, in a battery EIS application, the AC voltage Vac signal component could have a peak voltage of the order of 5 mV, whereas the DC voltage signal component Vdc could have a magnitude of the order of 3.7V.

The AC voltage component of the EIS measurement signal is a response to the AC stimulus current signal supplied by the signal generator circuitry 110. If the signal generator circuitry 110 is integrated in the same IC die as the ADC 130, EIS processing circuitry 140 and other associated circuitry (not shown in FIG. 1), the AC stimulus current signal can cause power dissipation in the form of heat (due to, for example, I²R effects arising from the current of the AC stimulus signal and the resistance of the IC die), which can modulate the temperature of the IC die at low frequencies of the AC stimulus current signal. Such modulation of the temperature of the IC die can cause fluctuations in the output voltage of a reference circuit of the IC (e.g. a bandgap reference circuit) that supplies a reference voltage to the ADC circuitry 130. This fluctuating reference voltage can modulate the DC voltage signal component Vdc of the EIS measurement signal, creating a parasitic tone at the frequency of the AC stimulus current signal. This parasitic tone adds to the EIS measurement voltage signal and gives rise to the measurement error discussed above.

### SUMMARY

According to a first aspect, the invention provides a system for performing a measurement on a component, the system comprising: an integrated circuit (IC) comprising: analog to digital (ADC) converter circuitry; and processing circuitry, wherein the system further comprises: difference circuitry, wherein: the difference circuitry is operable to generate a compensated measurement voltage by subtracting a compensation voltage received from a voltage source external to the integrated circuit from a measurement voltage output by the component in response to a stimulus signal received by the component; the ADC circuitry is configured to convert the compensated measurement voltage into a digital compensated measurement signal; and the measurement circuitry is configured to generate a measurement result based on the digital compensated measurement signal.

The IC may further comprise signal generator circuitry configured to generate the stimulus signal for application to the component.

The stimulus signal may comprise an AC current signal.

A frequency of the stimulus signal may be variable.

The difference circuitry may comprise subtractor circuitry. Alternatively, the difference circuitry may comprise difference amplifier circuitry.

The IC may further comprise the difference circuitry.

The difference circuitry may be external to the IC.

The difference circuitry may comprise analog difference circuitry.

The voltage source may be operative to supply a constant compensation voltage.

The constant compensation voltage may be provided by or derived from a power rail of a system incorporating the system for performing the measurement on the component.

The voltage source may be operative to output a variable compensation voltage that tracks a DC component of the measurement voltage output by the component.

The variable compensation voltage may be provided by or derived from a system configured to track a DC voltage of or associated with the component.

The component may be a battery or electrochemical cell, and the variable compensation voltage may be provided by or derived from a fuel gauge IC.

The system may be selectively operable in either a first mode or a second mode based on a frequency of the stimulus signal. In the first mode the compensation voltage may be subtracted from the measurement voltage, and in the second mode no compensation voltage may be subtracted from the measurement voltage.

The system may further comprise control circuitry configured to: compare the frequency of the stimulus signal to a threshold frequency; and responsive to a determination that the frequency of the stimulus signal is equal to or lower than the threshold, control the system to operate in the first mode, and responsive to a determination that the frequency of the stimulus signal is greater than the threshold, control the system to operate in the second mode.

In the second mode one or both of the difference circuitry and the voltage source may be disabled, and in the first mode both the difference circuitry and the voltage source may be enabled.

The component may comprise a battery or electrochemical cell.

The measurement result may comprise an indication of an impedance of the battery or electrochemical cell.

According to a second aspect the invention provides a host device comprising the system of the first aspect.

The host device may comprise, for example, a laptop, notebook, netbook or tablet computer, a gaming device, a games console, a controller for a games console, a virtual reality (VR) or augmented reality (AR) device, a mobile telephone, a portable audio player, a portable device, an accessory device for use with a laptop, notebook, netbook or tablet computer, a gaming device, a games console a VR or AR device, a mobile telephone, a portable audio player or other portable device.

According to a third aspect, the invention provides a system for performing a measurement on a component, the system comprising: an integrated circuit (IC) comprising: analog to digital (ADC) converter circuitry; and processing circuitry, wherein the system further comprises: a voltage source external to the integrated circuit; and difference circuitry, wherein: the ADC circuitry is configured to convert a measurement voltage output by the component in response to a stimulus signal received by the component into a digital measurement signal; the voltage source is configured to supply a compensation voltage; the difference circuitry is operable to generate a digital compensated measurement voltage by subtracting a digital version of the compensation voltage from the digital measurement signal; and the measurement circuitry is configured to generate a measurement result based on the digital compensated measurement signal.

According to a fourth aspect, the invention provides an integrated circuit comprising for implementing a system for performing a measurement on a component, the integrated circuit comprising: analog to digital (ADC) converter circuitry; processing circuitry; and difference circuitry, wherein: the difference circuitry is operable to generate a compensated measurement signal by subtracting a signal indicative of a compensation voltage received from a voltage source external to the integrated circuit from a signal indicative of a measurement voltage output by the component in response to a stimulus signal received by the component; the measurement circuitry is configured to generate a measurement result based on a digital signal indicative of the compensated measurement signal.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

Embodiments of the invention will now be described, strictly by way of example only, with reference to the accompanying drawings, of which:

FIG. 1 is a schematic representation of an example EIS measurement system;

FIG. 2 illustrates a measurement error in EIS measurement results for an IC or chip having a built-in EIS system;

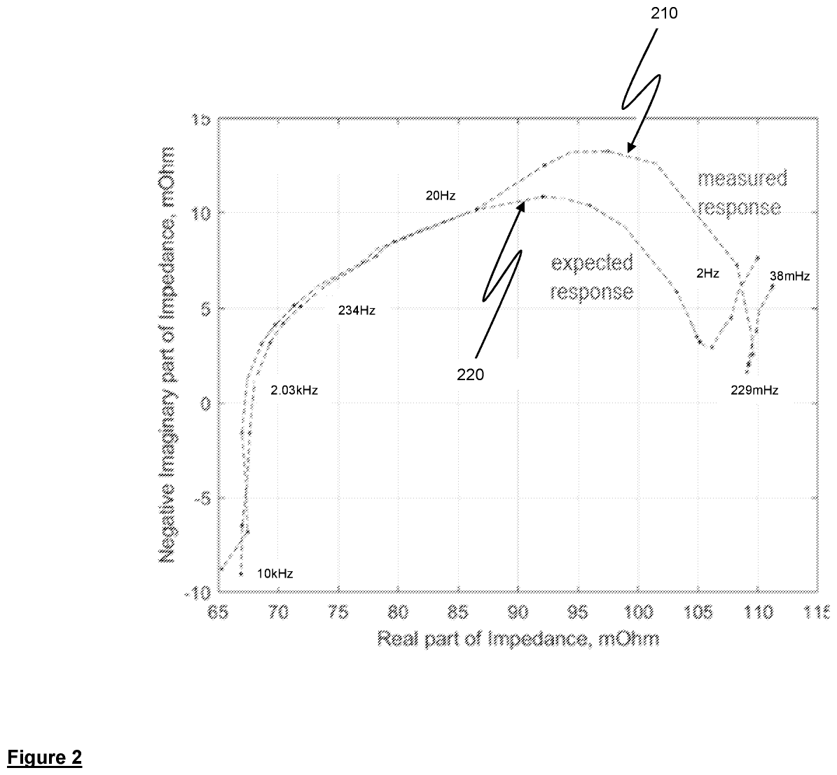

FIG. 3 is a schematic representation of an example EIS measurement system according to the present disclosure; and

FIG. 4 is a schematic representation of an alternative example EIS measurement system according to the present disclosure.

### DETAILED DESCRIPTION

The present disclosure proposes to eliminate, minimise or at least reduce measurement error in an on-chip EIS measurement system, by removing, cancelling, attenuating or compensating for the DC voltage signal component Vdc of the EIS measurement voltage signal output by the component 120, thereby eliminating or reducing thermal modulation of the DC voltage signal component and thus eliminating or attenuating the parasitic tone at the frequency of the AC stimulus current signal.

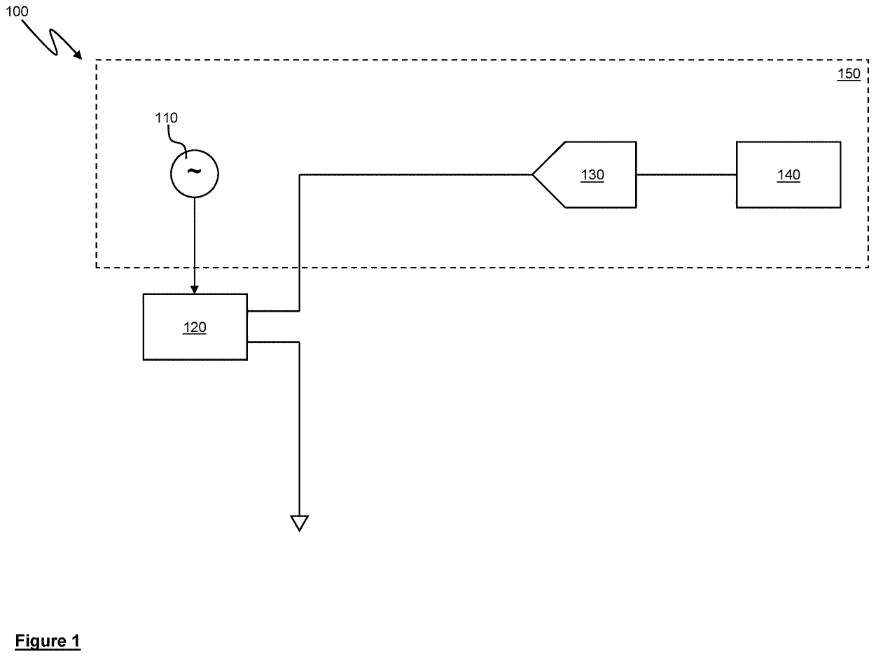

As DC voltage signal component Vdc of the EIS measurement voltage signal is a significant cause of the measurement error in the EIS measurement results generated by the EIS processing circuitry 140 of the EIS measurement system 100 of FIG. 1, removing or significantly reducing this voltage should reduce the associated error.

Known approaches to DC signal component removal include the use of a high-pass filter in the analog domain, to attenuate low frequency components, and the use of an on-chip digital filter or servo. However, such approaches are not suitable for removing the DC signal component in an on-chip EIS system.

For example, an analog low-pass filter would require excessively large and costly components (e.g. a large capacitor external to the IC 150 implementing the EIS system), because of the need to block or significantly attenuate the DC signal component but still pass low frequency signals (e.g. signals having a frequency of the order of tens of millihertz) that may provide useful information about the state of the component.

A digital filter or servo implemented on-chip (i.e. on the same IC 150 as the EIS system) would be subject to the same reference voltage error, and thus may compound the problem instead of alleviating it.

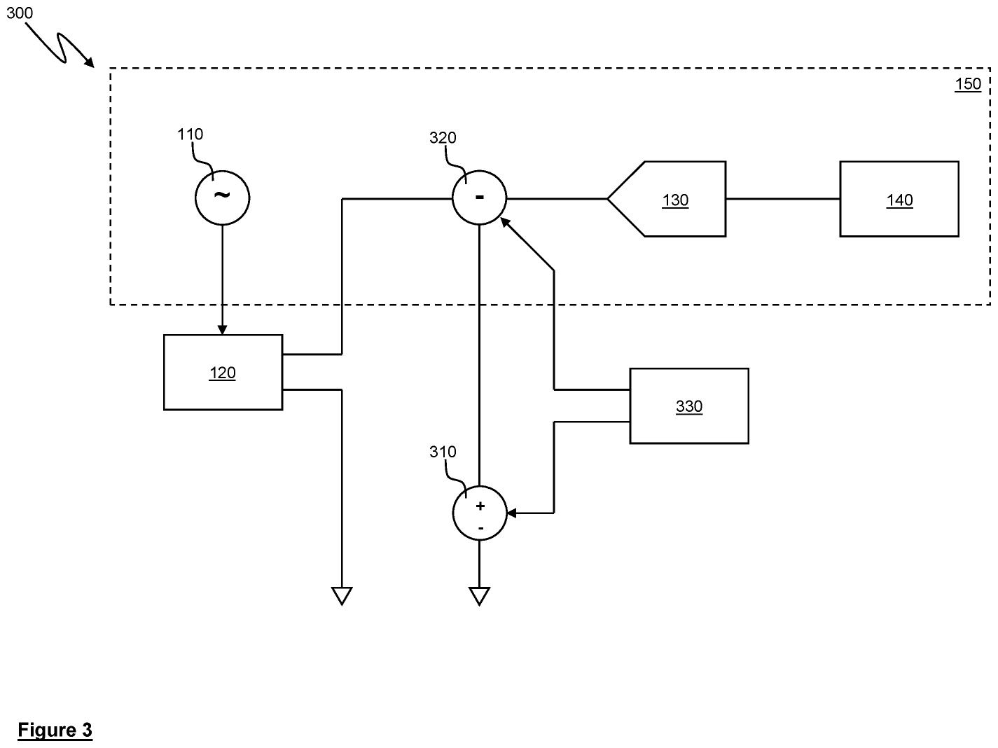

FIG. 3 is a schematic representation of an EIS measurement system according to the present disclosure.

The EIS measurement system, shown generally at 300 in FIG. 3, includes a number of elements in common with the EIS measurement system 100 of FIG. 1. Such common elements are denoted by common reference numerals in FIGS. 1 and 3 and will not be described again here, for the sake of clarity and brevity.

The EIS measurement system 300 differs from the EIS measurement system 100 in that it includes a voltage source 310, which is external to the IC 150 on which the signal generator circuitry 110, ADC circuitry 130 and EIS processing circuitry 140 are implemented.

The external voltage source 310 is configured to generate a compensation voltage for removing, cancelling, attenuating or compensating for the DC voltage signal component Vdc of the EIS measurement signal output by the component 120.

The EIS measurement system 300 further comprises difference circuitry 320, which may be implemented on the IC or externally of the IC. The difference circuitry 320 may comprise, for example, difference amplifier circuitry or subtractor circuitry.

A first input of the difference circuitry 320 is coupled (in use of the EIS measurement system 300) to an output of the component 120, and a second input of the difference circuitry 320 is coupled (in use of the EIS measurement system 300) to an output of the external voltage source 310. An output of the difference circuitry 320 is coupled to an input of the ADC circuitry 130.

The difference circuitry 320 is configured to subtract the compensation voltage generated by the external voltage source 310 from the EIS measurement voltage signal output by the component 120, to generate a compensated measurement voltage signal in which the DC voltage signal component Vdc of the EIS measurement voltage signal output by the component 120 has been removed, cancelled, attenuated or otherwise compensated for.

This compensated measurement voltage signal is output to the input of the ADC circuitry 130, which generates an outputs a digital compensated measurement signal to the EIS processing circuitry 140, which processes the digital compensated measurement signal to generate one or more EIS measurement outputs.

The external voltage source 310 may be configured to output a constant DC voltage as the compensation voltage. For example, the external voltage source 310 may be a power rail of a larger system (e.g. a host device such as a mobile telephone or the like) in which the EIS measurement system 300 is incorporated, or may be configured to supply a constant DC voltage derived from a power rail of such a larger system. The magnitude of the constant DC voltage may be selected to correspond (at least approximately) to a nominal output voltage of the component 120. For example, where the component 120 is a battery or other electrochemical cell having a nominal output voltage of 3.7V, the external voltage source may be a 3.7V power rail of the larger system, or may be configured to generate a constant voltage of 3.7V based on a voltage received from a power rail of the larger system.

By subtracting a constant compensation voltage from the EIS measurement voltage signal output by the component 120, the DC voltage signal component Vdc of the EIS measurement voltage signal can be cancelled or significantly attenuated. This approach may result in some noise in the EIS measurement system 300, but the use of a constant DC voltage as the compensation voltage may result is a high level (e.g. 80% or greater) of error reduction.

Alternatively, the external voltage source 310 may be configured to provide an output voltage that varies according to an output voltage of the component 120 as the compensation voltage, such that the compensation voltage supplied by the external voltage source 310 can track the DC voltage signal component Vdc of the EIS measurement signal output by the component 120.

For example, the external voltage source may comprise a voltage source of a system, external to the EIS measurement system 300, that is configured to track or monitor a DC output voltage of the component 120 (or some other DC voltage of or associated with the component 120), or may be configured to supply a variable compensation voltage based on or derived from such a system. In one example, where the component 120 is a battery or other electrochemical cell, the variable compensation voltage may be, or may be based on or derived from, an output of a fuel gauge integrated circuit that monitors the capacity of the battery or cell.

Supplying a variable compensation voltage that tracks the DC voltage signal component in this way can significantly reduce EIS measurement errors, as the DC voltage signal component Vdc can be more accurately cancelled than would be the case if a constant compensation voltage were used. This approach may therefore result in significant (e.g. of the order of 95%) EIS measurement error reduction.

The EIS measurement system 300 may further comprise control circuitry 330, configured to output control signals to the external voltage source 310 and/or the difference circuitry 320 to enable or disable the difference circuitry 320 and/or the external voltage source 310 based on a frequency of the AC stimulus current signal output by the signal generator circuitry 110. Thus, a first output of the control circuitry 330 may be coupled to a control input of the difference circuitry 320 and a second output of the control circuitry 330 may be coupled to a control input of the external voltage source 310. An input of the control circuitry 330 (not shown in FIG. 3 for clarity) is coupled to the output of the signal generator circuitry 110, such that the control circuitry receives the AC stimulus current signal output by the signal generator circuitry 110.

In operation of the EIS measurement system 300, the signal generator circuitry 110 generates and outputs a variable frequency AC stimulus current signal to the component 120. For example, the frequency of the AC stimulus current signal output by the signal generator circuitry 110 may start at an upper limit or bound (e.g. 10 kHz) of a predefined frequency range, and may decrease (either continuously or in a sequence of discrete steps) to a lower limit or bound (e.g. 20 mHz) over a predefined period of time. Alternatively, the frequency of the AC stimulus current signal may start at the lower limit or bound of the predefined frequency range and increase (either continuously or in a sequence of discrete steps) to the upper limit or bound over a predefined period of time.

The control circuitry 330 may compare the frequency of the AC stimulus current signal to a threshold frequency (e.g. 20 Hz), and may enable or disable the difference circuitry 320 and/or the external voltage source 310 based on this comparison. When the frequency of the AC stimulus current signal is equal to or less than the threshold frequency, the difference circuitry 320 and/or the external voltage source 310 are enabled to apply the compensation voltage to the EIS measurement voltage signal output by the component 120, to facilitate accurate measurement at low AC stimulus current signal frequencies. When the frequency of the AC stimulus current signal is greater than the threshold frequency, the difference circuitry 320 and/or the external voltage source 310 are disabled, such that the compensation voltage is not applied to the EIS measurement voltage signal output by the component 120.

Thus, the EIS measurement system 300 is operable in two modes of operation: a first, low frequency, mode in which the difference circuitry 320 and/or the external voltage source 310 are enabled to reduce measurement error at low (e.g. 20 Hz or lower) AC stimulus current signal frequencies; and a second, higher frequency, mode in which the which the difference circuitry 320 and/or the external voltage source 310 are disabled because the compensation voltage is not required to improve measurement accuracy at higher (e.g. greater than 20 Hz) AC stimulus current signal frequencies.

In the example shown in FIG. 3, the difference circuitry 320 comprises analog difference circuitry. It is conceivable, however, that digital difference circuitry could be used instead of analog difference circuitry.

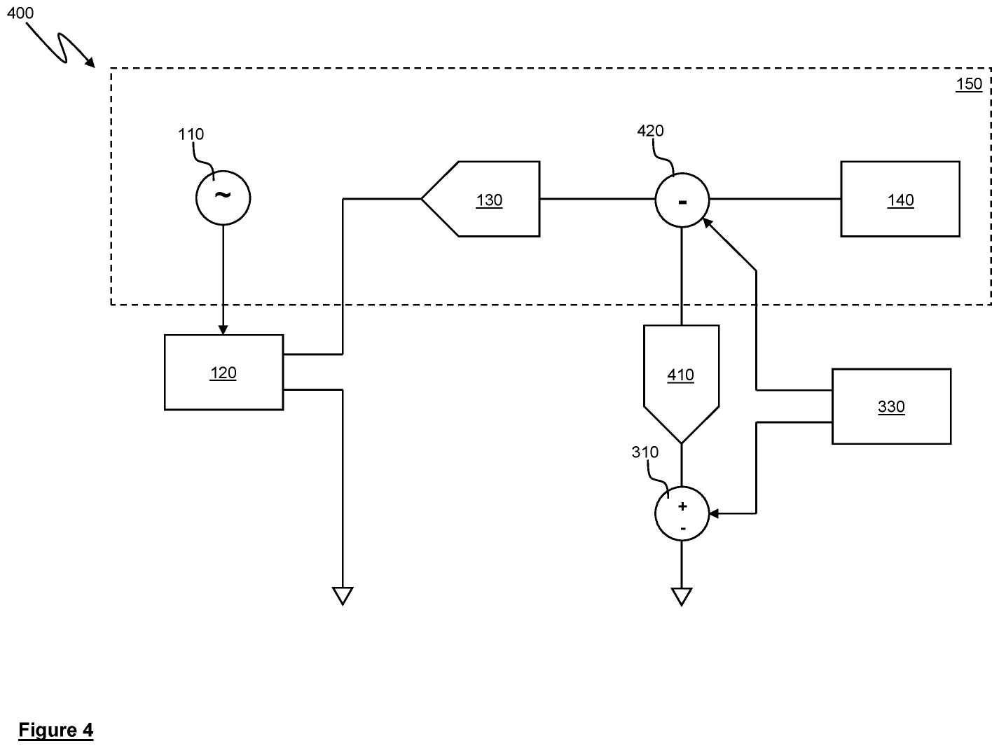

FIG. 4 is a schematic representation of an example of an EIS measurement system that uses digital difference circuitry instead of analog difference circuitry. The EIS measurement system, shown generally at 400 in FIG. 4, includes many elements in common with the EIS measurement system 300 of FIG. 3. Such common elements are denoted by common reference numerals in FIGS. 3 and 4, and will not be described again here, for the sake of clarity and brevity.

Compared to the EIS measurement system 300 of FIG. 3, the EIS measurement system 400 include additional ADC circuitry 410 for converting the compensation voltage provided by the external voltage source 310 into a digital compensation signal. The EIS measurement system 400 further includes digital difference circuitry 420 configured to subtract this digital compensation signal from a digital measurement signal output by the ADC circuitry 130, to generate a compensated digital signal for processing by the EIS processing circuitry 140 to generate one or more EIS measurement results.

The foregoing description explains the present disclosure in the context of an EIS measurement system which removes, cancels, attenuates or otherwise compensate for a DC voltage signal component of a measurement signal output by a component in response to an AC stimulus signal, to reduce measurement error at low frequencies of the AC stimulus signal. Those or ordinary skill in the art will readily appreciate that the principles of the present disclosure are equally applicable to other measurement systems and applications where the presence of a DC component in a signal can lead to error in measurements that are based on a low-frequency AC stimulus signal. Thus it will be understood that the present disclosure is not limited to EIS measurement systems, but also encompasses other measurement systems that apply a low frequency AC stimulus signal to a component to generate a measurement signal comprising a superposition of an AC signal component on a DC signal component.

As will be apparent from the foregoing description, the measurement system of the present disclosure permits reduced measurement error (and thus improved measurement accuracy) for measurements based on a low frequency stimulation signal.

The circuitry, system and techniques described above with reference to the accompanying drawings may be incorporated in a host device such as a laptop, notebook, netbook or tablet computer, a gaming device such as a games console or a controller for a games console, a virtual reality (VR) or augmented reality (AR) device, a mobile telephone, a portable audio player or some other portable device, or may be incorporated in an accessory device for use with a laptop, notebook, netbook or tablet computer, a gaming device, a VR or AR device, a mobile telephone, a portable audio player or other portable device.

The skilled person will recognise that some aspects of the above-described apparatus and methods may be embodied as processor control code, for example on a non-volatile carrier medium such as a disk, CD- or DVD-ROM, programmed memory such as read only memory (Firmware), or on a data carrier such as an optical or electrical signal carrier. For many applications embodiments of the invention will be implemented on a DSP (Digital Signal Processor), ASIC (Application Specific Integrated Circuit) or FPGA (Field Programmable Gate Array). Thus the code may comprise conventional program code or microcode or, for example code for setting up or controlling an ASIC or FPGA. The code may also comprise code for dynamically configuring re-configurable apparatus such as re-programmable logic gate arrays. Similarly the code may comprise code for a hardware description language such as Verilog™ or VHDL (Very high speed integrated circuit Hardware Description Language). As the skilled person will appreciate, the code may be distributed between a plurality of coupled components in communication with one another. Where appropriate, the embodiments may also be implemented using code running on a field-(re)programmable analogue array or similar device in order to configure analogue hardware.

Note that as used herein the term module shall be used to refer to a functional unit or block which may be implemented at least partly by dedicated hardware components such as custom defined circuitry and/or at least partly be implemented by one or more software processors or appropriate code running on a suitable general purpose processor or the like. A module may itself comprise other modules or functional units. A module may be provided by multiple components or sub-modules which need not be co-located and could be provided on different integrated circuits and/or running on different processors.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

1. A system for performing a measurement on a component, the system comprising:
an integrated circuit (IC) comprising:
analog to digital (ADC) converter circuitry; and
processing circuitry,
wherein the system further comprises:
difference circuitry,
wherein:
the difference circuitry is operable to generate a compensated measurement voltage by subtracting a compensation voltage received from a voltage source external to the integrated circuit from a measurement voltage output by the component in response to a stimulus signal received by the component;
the ADC circuitry is configured to convert the compensated measurement voltage into a digital compensated measurement signal; and
the measurement circuitry is configured to generate a measurement result based on the digital compensated measurement signal.

2. The system of claim 1, wherein the IC further comprises signal generator circuitry configured to generate the stimulus signal for application to the component.

3. The system of claim 2, wherein the stimulus signal comprises an AC current signal.

4. The system of claim 3, wherein a frequency of the stimulus signal is variable.

5. The system of claim 1, wherein the difference circuitry comprises subtractor circuitry or difference amplifier circuitry.

6. The system of claim 1, wherein the IC further comprises the difference circuitry.

7. The system of claim 1, wherein the difference circuitry is external to the IC.

8. The system of claim 1, wherein the difference circuitry comprises analog difference circuitry.

9. The system of claim 1, wherein the voltage source is operative to supply a constant compensation voltage.

10. The system of claim 9, wherein the constant compensation voltage is provided by or derived from a power rail of a system incorporating the system for performing the measurement on the component.

11. The system of claim 1, wherein the voltage source is operative to output a variable compensation voltage that tracks a DC component of the measurement voltage output by the component.

12. The system of claim 11, wherein the variable compensation voltage is provided by or derived from a system configured to track a DC voltage of or associated with the component.

13. The system of claim 12, wherein:
the component is a battery or electrochemical cell; and
the variable compensation voltage is provided by or derived from a fuel gauge IC.

14. The system of claim 1, wherein the system is selectively operable in either a first mode or a second mode based on a frequency of the stimulus signal, wherein:
in the first mode the compensation voltage is subtracted from the measurement voltage; and
in the second mode no compensation voltage is subtracted from the measurement voltage.

15. The system of claim 14, further comprising control circuitry configured to:
compare the frequency of the stimulus signal to a threshold frequency; and
responsive to a determination that the frequency of the stimulus signal is equal to or lower than the threshold, control the system to operate in the first mode, and
responsive to a determination that the frequency of the stimulus signal is greater than the threshold, control the system to operate in the second mode.

16. The system of claim 14, wherein in the second mode one or both of the difference circuitry and the voltage source are disabled, and wherein in the first mode both the difference circuitry and the voltage source are enabled.

17. The system of claim 1, wherein the component comprises a battery or electrochemical cell.

18. The system of claim 17, wherein the measurement result comprises an indication of an impedance of the battery or electrochemical cell.

19. A host device comprising the system of claim 1.

20. A host device according to claim 19, wherein the host device comprises a laptop, notebook, netbook or tablet computer, a gaming device, a games console, a controller for a games console, a virtual reality (VR) or augmented reality (AR) device, a mobile telephone, a portable audio player, a portable device, an accessory device for use with a laptop, notebook, netbook or tablet computer, a gaming device, a games console a VR or AR device, a mobile telephone, a portable audio player or other portable device.

21. A system for performing a measurement on a component, the system comprising:
an integrated circuit (IC) comprising:
analog to digital (ADC) converter circuitry; and
processing circuitry,
wherein the system further comprises:
a voltage source external to the integrated circuit; and
difference circuitry,
wherein:
the ADC circuitry is configured to convert a measurement voltage output by the component in response to a stimulus signal received by the component into a digital measurement signal;
the voltage source is configured to supply a compensation voltage;
the difference circuitry is operable to generate a digital compensated measurement voltage by subtracting a digital version of the compensation voltage from the digital measurement signal; and
the measurement circuitry is configured to generate a measurement result based on the digital compensated measurement signal.

22. An integrated circuit comprising for implementing a system for performing a measurement on a component, the integrated circuit comprising:
analog to digital (ADC) converter circuitry;
processing circuitry; and
difference circuitry,
wherein:
the difference circuitry is operable to generate a compensated measurement signal by subtracting a signal indicative of a compensation voltage received from a voltage source external to the integrated circuit from a signal indicative of a measurement voltage output by the component in response to a stimulus signal received by the component;
the measurement circuitry is configured to generate a measurement result based on a digital signal indicative of the compensated measurement signal.
